(19) United States
(12) Patent Application Publication
(10) Pub. No.: US 2025/0072228 A1
(43) Pub. Date: Feb. 27, 2025

(54) DISPLAY APPARATUS AND METHOD OF MANUFACTURING THE SAME

(71) Applicant: Samsung Display Co., Ltd., Yongin-si (KR)

(72) Inventors: Heewoon Im, Yongin-si (KR); Jiyoon Kim, Yongin-si (KR); Yukhyun Nam, Yongin-si (KR); Jaehyun Park, Yongin-si (KR)

(73) Assignee: Samsung Display Co., Ltd., Yongin-si (KR)

(21) Appl. No.: 18/807,005

(22) Filed: Aug. 16, 2024

(30) Foreign Application Priority Data
Aug. 22, 2023 (KR) 10-2023-0110135

(51) Int. Cl. H10K 59/122; H10K 50/115

(52) U.S. Cl. CPC H10K 59/122; H10K 50/115

(57) ABSTRACT

A display apparatus includes a substrate, a first light-emitting diode, a second light-emitting diode, and a third light-emitting diode disposed on the substrate and configured to emit light of different colors, and a hydrogen supply layer arranged to overlap or to be adjacent to each of the first light-emitting diode and the second light-emitting diode, wherein each of the first, second and third light emitting diodes include a pixel electrode, an intermediate layer disposed on the pixel electrode and in an opening in the bank layer, and an opposite electrode covering the intermediate layer and the bank layer.

### CROSS-REFERENCE TO RELATED APPLICATIONS

This application claims priority under 35 U.S.C. § 119 from Korean Patent Application No. 10-2023-0110135 filed on Aug. 22, 2023 in the Korean Intellectual Property Office, the entire contents of which are incorporated herein by reference.

### BACKGROUND

### 1. Technical Field

One or more embodiments relate to a structure of a display apparatus and a method of manufacturing the display apparatus.

### 2. Description of the Related Art

Generally, a display apparatus includes light-emitting elements and thin-film transistors on a substrate and operates according to light-emission of the light-emitting elements. A light-emitting element may be an element configured to convert electrical energy into light energy. Examples of a light-emitting element include an organic light-emitting element in which a light-emitting material may be an organic material and a quantum-dot light-emitting element in which a light-emitting material may be a quantum-dot.

Specifically, each pixel of a display apparatus includes a light-emitting element including an intermediate layer, wherein the intermediate layer includes an emission layer between a pixel electrode and an opposite electrode. A display apparatus may be configured to control each pixel to emit light or the degree of light emission through a thin-film transistor electrically connected to the pixel electrode. Some layers included in the intermediate layer of the light-emitting element may be commonly provided over multiple light-emitting elements.

### SUMMARY

One or more embodiments include a display apparatus including a light-emitting element having a high emission efficiency and a long lifespan. However, such a technical problem may be just an example, and the disclosure may not be limited thereto.

Additional aspects will be set forth in part in the description which follows and, in part, will be apparent from the description, or may be learned by practice of the presented embodiments of the disclosure.

According to one or more embodiments, a display apparatus may include a substrate, a first light-emitting diode, a second light-emitting diode, and a third light-emitting diode disposed on the substrate and configured to emit light of different colors, and a hydrogen supply layer arranged to overlap or to be adjacent to each of the first light-emitting diode and the second light-emitting diode, wherein the first, second and third light emitting diodes may each include a pixel electrode disposed on the substrate, the bank layer including an opening exposing a central portion of the pixel electrode, an intermediate layer disposed on the pixel electrode and in the opening, and an opposite electrode disposed on the intermediate layer and on the bank layer.

The hydrogen supply layer may not overlap the third light-emitting diode, and the hydrogen supply layer may be arranged not to be adjacent to the third light-emitting diode.

The hydrogen supply layer may comprise hydrogen; and at least one of silicon nitride (SiNₓ), silicon oxide (SiOₓ), and silicon oxynitride (SiON).

The first light-emitting diode may include a first pixel electrode, the second light-emitting diode may include a second pixel electrode, and the third light-emitting diode may include a third pixel electrode, the bank layer may include a first opening exposing a central portion of the first pixel electrode, a second opening exposing a central portion of the second pixel electrode, and a third opening exposing a central portion of the third pixel electrode, and the first light-emitting diode may further include a first intermediate layer disposed in the first opening, the second light-emitting diode may further include a second intermediate layer disposed in the second opening, and the third light-emitting diode may further include a third intermediate layer disposed in the third opening.

The hydrogen supply layer may be disposed under and is overlapped by each of the first pixel electrode and the second pixel electrode.

An upper surface of the hydrogen supply layer may be in contact with a bottom surface of at least one of the first pixel electrode and the second pixel electrode.

The bank layer may cover ends of each of the first pixel electrode, the second pixel electrode, and the hydrogen supply layer.

In a plan view, the hydrogen supply layer and at least one of the first pixel electrode and the second pixel electrode may have a same area.

A thickness of each of the first pixel electrode and the second pixel electrode may be in a range of about 500 Å to about 1,500 Å.

The hydrogen supply layer may be disposed on an upper portion of the first pixel electrode and an upper portion of the second pixel electrode, and the hydrogen supply layer may include a first hydrogen supply layer opening exposing the central portion of the first pixel electrode, and a second hydrogen supply layer opening exposing the central portion of the second pixel electrode.

The hydrogen supply layer may cover ends of the first pixel electrode and the second pixel electrode.

A lateral surface of the hydrogen supply layer facing the first light-emitting diode may be in direct contact with the first intermediate layer, and a lateral surface of the hydrogen supply layer facing the second light-emitting diode may be in direct contact with the second intermediate layer.

The first hydrogen supply layer opening may overlap the first opening, and the second hydrogen supply layer opening may overlap the second opening.

The bank layer may be disposed on the hydrogen supply layer.

An entire lower surface of the bank layer arranged between the first light-emitting diode and the second light-emitting diode may be in contact with an upper surface of the hydrogen supply layer.

The display apparatus may further include a planarization layer disposed under each of the first pixel electrode, the second pixel electrode, and the third pixel electrode, wherein a portion of a lower surface of the bank layer arranged between the first light-emitting diode and the third light-emitting diode may be in contact with an upper surface of the hydrogen supply layer, and a remaining portion may be in contact with an upper surface of the planarization layer.

A portion of the lower surface of the bank layer arranged between the second light-emitting diode and the third light-emitting diode may be in contact with the upper surface of the hydrogen supply layer, and a remaining portion may be in contact with the upper surface of the planarization layer.

The display apparatus may further include an encapsulation substrate disposed on the first light-emitting diode, the second light-emitting diode, and the third light-emitting diode, and a sealing member coupling the substrate to the encapsulation substrate, wherein the hydrogen supply layer may be in contact with a surface of the encapsulation substrate facing the substrate.

The hydrogen supply layer may be arranged to overlap each of the first intermediate layer and the second intermediate layer.

The hydrogen supply layer may be in contact with an upper surface of the opposite electrode.

Each of the first intermediate layer and the second intermediate layer may include an emission layer including a plurality of quantum dots, and the third intermediate layer may include an emission layer composed of an organic material.

A thickness of the hydrogen supply layer may be in a range of about 1,000 Å to about 5,000 Å.

The first light-emitting diode may be configured to emit light in a wavelength band of about 580 nm to about 780 nm, the second light-emitting diode may be configured to emit light in a wavelength band of about 495 nm to about 580 nm, and the third light-emitting diode may be configured to emit light in a wavelength band of about 380 nm to about 495 nm.

According to one or more embodiments, a display apparatus may include a substrate, a quantum-dot light-emitting element disposed on the substrate, an organic light-emitting element disposed on the substrate, and a hydrogen supply layer arranged to overlap or to be adjacent to the quantum-dot light-emitting element, wherein the quantum-dot light-emitting element and the organic light-emitting element may each include a pixel electrode disposed on the substrate, the bank layer including an opening exposing a central portion of the pixel electrode, an intermediate layer disposed on the pixel electrode and in the opening, and an opposite electrode covering the intermediate layer and the bank layer.

The intermediate layer of the quantum-dot light-emitting element may include an emission layer that includes a plurality of quantum dots, and the intermediate layer of the organic light-emitting element may include an emission layer that is composed of an organic material.

The hydrogen supply layer may not overlap the organic light-emitting element and may be arranged not to be adjacent to the organic light-emitting element.

The hydrogen supply layer may overlap the pixel electrode of the quantum-dot light-emitting element and may be disposed under the pixel electrode of the quantum-dot light-emitting element.

The hydrogen supply layer may be disposed on the pixel electrode of the quantum-dot light-emitting element and may include a hydrogen supply layer opening exposing the central portion of the pixel electrode.

The display apparatus may further include an encapsulation substrate disposed on the quantum-dot light-emitting element and the organic light-emitting element, and a sealing member coupling the substrate to the encapsulation substrate, wherein the hydrogen supply layer may be in direct contact with a surface of the encapsulation substrate facing the substrate.

The hydrogen supply layer may be arranged to overlap the intermediate layer of the quantum-dot light-emitting element.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic diagram of an equivalent circuit of a pixel electrically connected to a light-emitting element included in a pixel of the display apparatus of FIG. 1;

FIGS. 3A and 3B are schematic cross-sectional views of a display apparatus according to embodiments;

FIG. 4 is a schematic plan view of a display apparatus according to an embodiment;

FIG. 5 is a schematic cross-sectional view of the display apparatus of FIG. 4 taken along line I-I′ of FIG. 4;

FIG. 6 is a schematic cross-sectional view of a display apparatus according to an embodiment; and

FIG. 7 is a schematic cross-sectional view of a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals and/or reference characters denote like elements.

In case that an element, such as a layer, is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that may not be perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” in case that used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, may not be necessarily intended to be limiting.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

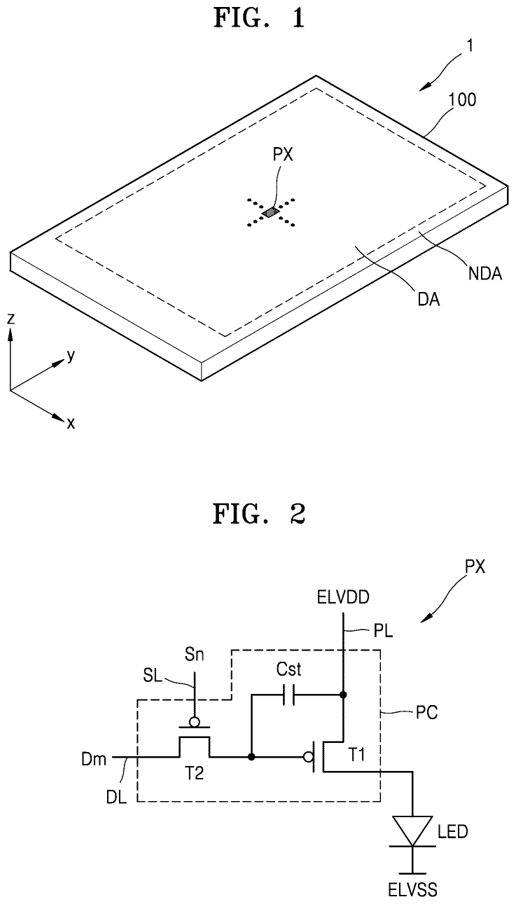

FIG. 1 is a schematic perspective view of a display apparatus 1 according to an embodiment.

Referring to FIG. 1, the display apparatus 1 may include a display area DA and a non-display area NDA on a substrate 100.

The display area DA may be configured to display images. Multiple pixels PX two-dimensionally arranged in a plan view may be arranged in the display area DA. In the specification, each pixel PX denotes a sub-pixel configured to emit light of a certain color. Each pixel PX may be, for example, one of a red sub-pixel, a green sub-pixel, and a blue sub-pixel. The display apparatus 1 may be configured to display images according to light emitted from the pixels PX.

The non-display area NDA may be a region configured not to display images, and the pixels PX may not be arranged in the non-display area NDA. The non-display area NDA may surround the display area DA entirely. A driver or a voltage line configured to provide electrical signals or power to the pixels PX may be arranged in the non-display area NDA. A pad portion (not shown) may be arranged in the non-display area NDA, wherein the pad portion may be a region to which electronic elements or a printed circuit board may be electrically connected.

The display area DA may have a polygonal shape. As an example, as shown in FIG. 1, the display area DA may have a rectangular shape in which a horizontal length thereof may be greater than a vertical length thereof. Alternatively, the display area DA may have a square shape. Alternatively, the display area DA may have various shapes such as an elliptical shape or a circular shape.

FIG. 2 is a schematic diagram of an equivalent circuit of a pixel electrically connected to a light-emitting element included in a pixel of the display apparatus of FIG. 1.

Referring to FIG. 2, the pixel PX may include a pixel circuit PC and a light-emitting element, for example, a light-emitting diode LED electrically connected to the pixel circuit PC. The pixel circuit PC may include a first thin-film transistor T1, a second thin-film transistor T2, and a storage capacitor Cst. Each pixel PX may be configured to emit, for example, red, green, or blue light, or emit red, green, blue, or white light by using the light-emitting diode LED.

The second thin-film transistor T2 may be a switching thin-film transistor, may be electrically connected to a scan line SL and a data line DL, and may be configured to transfer a data voltage or a data signal Dm to the first thin-film transistor T1 according to a switching voltage or a switching signal Sn, the data voltage being input from the data line DL, and the switching voltage being input from the scan line SL. The storage capacitor Cst may be electrically connected to the second thin-film transistor T2 and a driving voltage line PL and configured to store a voltage corresponding to a difference between a voltage transferred from the second thin-film transistor T2 and a first power voltage ELVDD supplied to the driving voltage line PL.

The first thin-film transistor T1 may be a driving thin-film transistor, may be electrically connected to the driving voltage line PL and the storage capacitor Cst, and may be configured to control a driving current according to the voltage stored in the storage capacitor Cst, the driving current flowing from the driving voltage line PL to the light-emitting diode LED. The light-emitting diode LED may be configured to emit light having a preset brightness corresponding to the driving current. An opposite electrode (e.g., a cathode) of the light-emitting diode LED may receive a second power voltage ELVSS.

Although it may be shown in FIG. 2 that the pixel circuit PC includes two thin-film transistors and one storage capacitor, the number of thin-film transistors and the number of storage capacitors may be variously changed depending on the design of the pixel circuit PC.

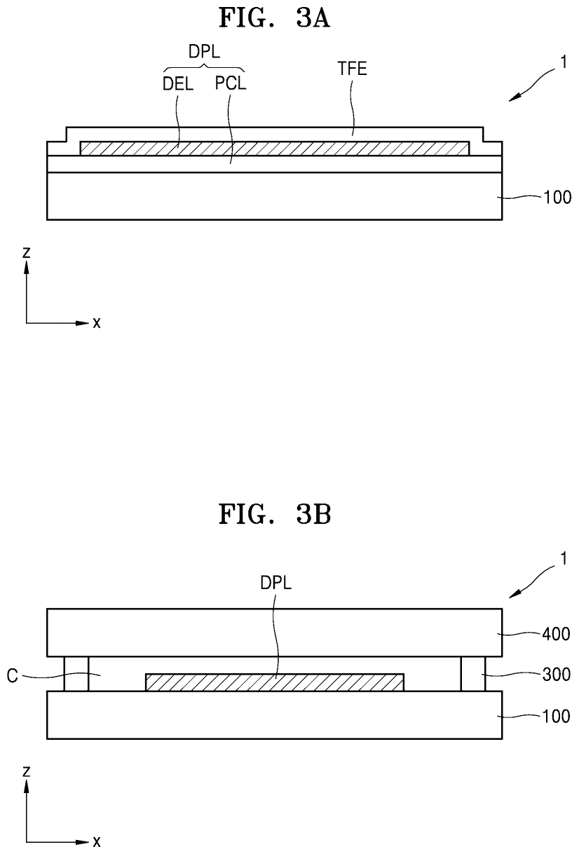

FIG. 3A is a schematic cross-sectional view of the display apparatus according to an embodiment, and FIG. 3B is a schematic cross-sectional view of a display apparatus according to an embodiment.

Referring to FIG. 3A, a display layer DPL and a thin-film encapsulation layer TFE may be provided on the substrate 100 of the display apparatus 1. The display layer DPL may include a pixel circuit layer PCL and a display element layer DEL, wherein the pixel circuit layer PCL includes the pixel circuit and insulating layers, and the display element layer DEL may be disposed on the pixel circuit layer PCL and may include multiple display elements.

The substrate 100 may include glass, metal, polymer resin, or a combination thereof. The polymer resin may include, for example, polyethersulfone, polyacrylate, polyetherimide, polyethylene naphthalate, polyethylene terephthalate, polyphenylene sulfide, polyarylate, polyimide, polycarbonate, cellulose acetate propionate, or a mixture thereof. The substrate 100 may have a multi-layered structure including two layers each including the polymer resin, and a barrier layer including an inorganic material (such as silicon oxide (SiOₓ), silicon nitride (SiNₓ), silicon oxynitride (SiON), or a combination thereof) therebetween. However, various modifications may be made.

The display element layer DEL may include display elements, for example, an organic light-emitting element, a quantum-dot light-emitting element, and the like. The pixel circuit layer PCL may include the pixel circuit electrically connected to the light-emitting element, and the pixel circuit layer PCL may further include the insulating layers. As an example, the pixel circuit layer PCL may include multiple transistors, multiple storage capacitors, and the insulating layers therebetween.

The display elements may be covered by an encapsulation member such as the thin-film encapsulation layer TFE. The thin-film encapsulation layer TFE may include at least one inorganic encapsulation layer and at least one organic encapsulation layer, each covering the display element layer DEL. The inorganic encapsulation layer may include an inorganic insulating material such as aluminum oxide (Al₂O₃), titanium oxide (TiO₂), tantalum oxide (Ta₂O₅), hafnium oxide (HfO₂), zinc oxide (ZnOₓ), silicon oxide (SiO₂), silicon nitride (SiNₓ), silicon oxynitride (SiON), or a combination thereof. The organic encapsulation layer may include a polymer-based material. The polymer-based material may include an acryl-based resin, an epoxy-based resin, polyimide, polyethylene, or a combination thereof. In an embodiment, the organic encapsulation layer may include acrylate.

Referring to FIG. 3B, the display layer DPL and an encapsulation substrate 400 may be provided on the substrate 100 of the display apparatus 1. A sealing member 300 may be disposed between the substrate 100 and the encapsulation substrate 400. The encapsulation substrate 400 may be a transparent member. The substrate 100 and the encapsulation substrate 400 may extend to each other by the sealing member 300, and a structure of an inner space between the substrate 100 and the encapsulation layer 400 may be provided. Moisture absorbents or fillers may be disposed in the inner space. The sealing member 300 may be a sealant. In an embodiment, the sealing member 300 may include a material cured by a laser beam. As an example, the sealing member 300 may include frit. Specifically, the sealing member 300 may include an organic sealant such as a urethane-based resin, an epoxy-based resin, an acrylic resin, or a combination thereof, or may include an inorganic sealant such as silicon. As a urethane-based resin, for example, urethane acrylate or the like may be used. As acrylic resin, for example, butyl acrylate, ethylhexyl acrylate, the like, or a combination thereof may be used. The sealing member 300 may include a material cured by heat.

In an embodiment, the display element layer DEL and the thin-film encapsulation layer TFE of FIG. 3A may be covered by the encapsulation substrate 400 and the sealing member 300 of FIG. 3B.

A touch electrode layer (not shown) may be disposed on the thin-film encapsulation layer TFE and/or the encapsulation substrate 400, and an optical functional layer (not shown) may be disposed on the touch electrode layer. The touch electrode layer may obtain coordinate information corresponding to an external input, for example, a touch event. The optical functional layer may reduce reflectivity of light (external light) incident toward the display apparatus 1 from the outside. Alternatively, the optical functional layer may increase color purity of light emitted from the display apparatus 1. In an embodiment, the optical functional layer may include a phase retarder and/or a polarizer. The retarder may include a film-type retarder or a liquid crystal-type retarder. The retarder may include a V/2 retarder and/or a/4 retarder. The polarizer may include a film-type polarizer or a liquid crystal-type polarizer. The film-type polarizer may include a stretchable synthetic resin film, and the liquid crystal-type polarizer may include liquid crystals arranged in an arrangement. Each of the phase retarder and the polarizer may further include a protective film.

In an embodiment, optical functional layer may include a black matrix and color filters. The color filters may be arranged by taking into account colors of light emitted respectively from the pixels of the display apparatus 1. The color filters may each include red, green, or blue pigment or dye. The color filters may each further include quantum dots in addition to the pigment or dye. Some of the color filters may not include pigment or dye, and may include scattering particles such as titanium oxide.

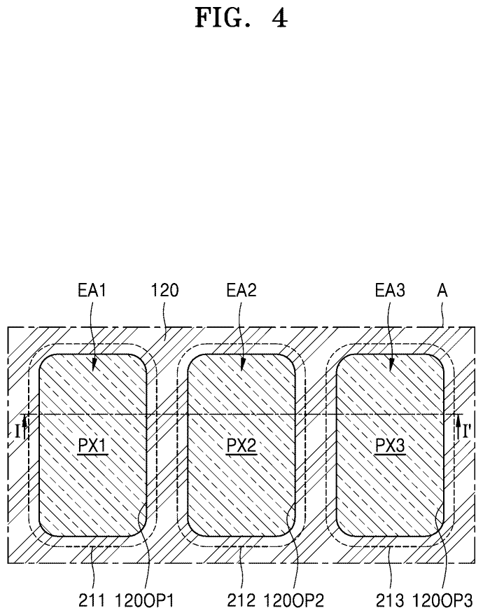

FIG. 4 is a schematic plan view of the display apparatus 1 according to an embodiment.

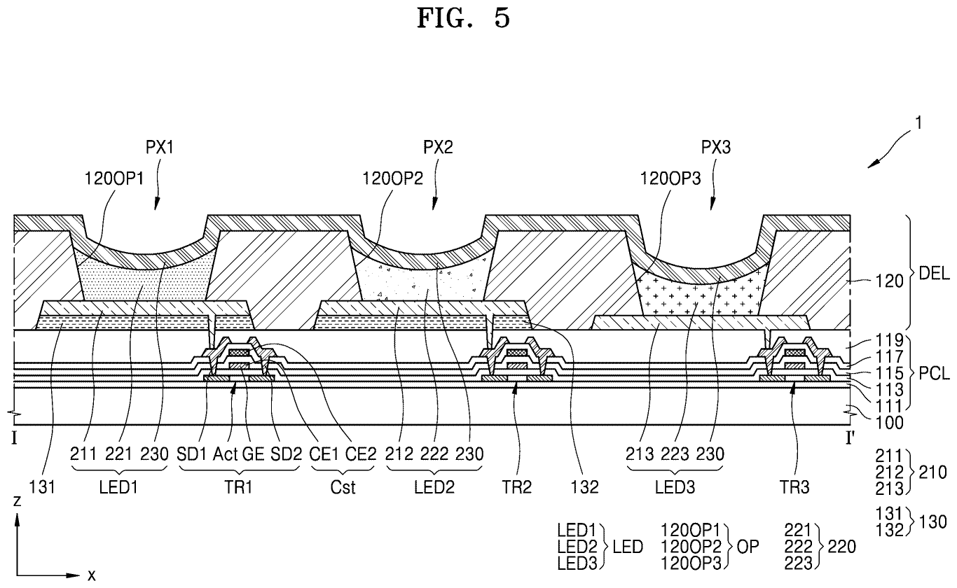

Referring to FIG. 4, the display apparatus 1 may include the pixels PX (see FIG. 1). The pixels PX (see FIG. 1) may include a first pixel PX1, a second pixel PX2, and a third pixel PX3. The first pixel PX1 may include a first light-emitting diode LED1 (see FIG. 5), the second pixel PX2 may include a second light-emitting diode LED2 (see FIG. 5), and the third pixel PX3 may include a third light-emitting diode LED3. The first pixel PX1, the second pixel PX2, and the third pixel PX3 may be respectively configured to emit light of different colors. As an example, the first pixel PX1 may be configured to emit red light, the second pixel PX2 may be configured to emit green light, and the third pixel PX3 may be configured to emit blue light. Red light may be light in a wavelength band of about 580 nm to about 780 nm, blue light may be light in a wavelength band of about 380 nm to about 495 nm, and green light may be light in a wavelength band of about 495 nm to about 580 nm.

Each light-emitting diode may include a pixel electrode, an opposite electrode, and an intermediate layer therebetween. Accordingly, the first pixel PX1 may include a first pixel electrode 211 of the first light-emitting diode LED1 (see FIG. 5), the second pixel PX2 may include a second pixel electrode 212 of the second light-emitting diode LED2 (see FIG. 5), and the third pixel PX3 may include a third pixel electrode 213 of the third light-emitting diode LED3 (see FIG. 5). The first pixel electrode 211, the second pixel electrode 212, and the third pixel electrode 213 may be apart from each other over the substrate 100 (see FIG. 5). In the present specification, “in a plan view” means “when an object is viewed from above”, where “above” means “in a direction perpendicular to the substrate 100.” That is, “A and B apart from each other in a plan view” means “A and B spaced apart from each other when viewed from above or in a direction perpendicular to the substrate 100.”

A bank layer 120 may be disposed on the first pixel electrode 211, the second pixel electrode 212, and the third pixel electrode 213, and may cover the edges of each of the first pixel electrode 211, the second pixel electrode 212, and the third pixel electrode 213. The bank layer 120 may include a first opening 120OP1 exposing the central portion of the first pixel electrode 211, a second opening 120OP2 exposing the central portion of the second pixel electrode 212, and a third opening 120OP3 exposing the central portion of the third pixel electrode 213.

Although not shown in FIG. 4, emission layers configured to emit light may be respectively disposed in the first opening 120OP1, the second opening 120OP2, the third opening 120OP3 of the bank layer 120. The opposite electrode may be disposed on the emission layers. As described above, a stack structure of the pixel electrode, the emission layer, and the opposite electrode may form one light-emitting diode. One opening of the bank layer 120 may correspond to one light-emitting diode and define an emission area.

As an example, an emission layer configured to emit red light may be disposed in the first opening 120OP1, which may define a first emission area EA1. Similarly, an emission layer configured to emit green light may be disposed in the second opening 120OP2, which may define a second emission area EA2. An emission layer configured to emit blue light may be disposed in the third opening 120OP3, which may define a third emission area EA3. Accordingly, the size of the area of the first opening 120OP1 is the same as the size of the area of the first emission area EA1, the size of the area of the second opening 120OP2 may be the same as the size of the area of the second emission area EA2, and the size of the area of the third opening 120OP3 may be the same as the size of the area of the third emission area EA3.

Each of the first opening 120OP1, the second opening 120OP2, and the third opening 120OP3 may have a polygonal shape when viewed in a direction (a z axis direction) perpendicular to the substrate 100 (see FIG. 5). In other words, each of the first emission area EA1, the second emission area EA2, and the third emission area EA3 may have a polygonal shape when viewed in a direction (the z axis direction) perpendicular to the substrate 100. It may be shown in FIG. 4 that each of the first emission area EA1, the second emission area EA2, and the third emission area EA3 has a quadrilateral shape, specifically, a quadrilateral shape having round edges when viewed in the direction (the z axis direction) perpendicular to the substrate 100. However, the embodiment may not be limited thereto. As an example, each of the first emission area EA1, the second emission area EA2, and the third emission area EA3 may have a circular shape or an elliptical shape when viewed in a direction (the z axis direction) perpendicular to the substrate 100.

FIG. 5 is a schematic cross-sectional view of the display apparatus of FIG. 4, taken along line I-I′ of FIG. 4.

Referring to FIG. 5, the pixel circuit layer PCL may be disposed on the substrate 100. The pixel circuit layer PCL may include first to third transistors TR1, TR2, and TR3, a buffer layer 111, a first gate insulating layer 113, a second gate insulating layer 115, an interlayer insulating layer 117, and a planarization layer 119 under and/or on elements of the transistor. Here, each of the first to third transistors TR1, TR2, and TR3 may correspond to the first thin-film transistor T1 shown in FIG. 2. Because the structure of the second transistor TR2 and the third transistor TR3 may be the same as or similar to the structure of the first transistor TR1, repeated description thereof may be omitted.

The buffer layer 111 may include an inorganic insulating material such as silicon nitride (SiNₓ), silicon oxynitride (SiON), silicon oxide (SiOₓ), or a combination thereof, and include a single-layered structure or a multi-layered structure including the inorganic insulating materials.

The buffer layer 111 may increase the flatness of the upper surface of the substrate 100 and prevent or reduce the penetration of impurities from the substrate 100 and the like into a semiconductor layer Act.

The first transistor TR1 may include the semiconductor layer Act, and the semiconductor layer Act may include polycrystalline silicon. Alternatively, the semiconductor layer Act may include amorphous silicon, an oxide semiconductor material, an organic semiconductor material, or a combination thereof.

A gate electrode GE may overlap a portion of the semiconductor layer Act. The gate electrode GE may include a conductive material. As an example, the gate electrode GE may include a conductive material such as molybdenum (Mo), aluminum (Al), copper (Cu), titanium (Ti), or a combination thereof and have a single-layered structure or a multi-layered structure including the above materials.

The first gate insulating layer 113 between the semiconductor layer Act and the gate electrode GE may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or a combination thereof.

The second gate insulating layer 115 may cover the gate electrode GE. Similar to the first gate insulating layer 113, the second gate insulating layer 115 may include an inorganic insulating material such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or a combination thereof.

An upper electrode CE2 of the storage capacitor Cst may be arranged on the second gate insulating layer 115. The upper electrode CE2 may overlap the gate electrode GE disposed below the upper electrode CE2. The gate electrode GE and the upper electrode CE2 overlapping each other with the second gate insulating layer 115 disposed therebetween may constitute the storage capacitor Cst. The gate electrode GE may serve as a lower electrode CE1 of the storage capacitor Cst.

As described above, the storage capacitor Cst may overlap the first transistor TR1. In an embodiment, the storage capacitor Cst may be disposed not to overlap the first transistor TR1.

The upper electrode CE2 may include a conductive material such as aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), copper (Cu), or a combination thereof, and include a single-layered structure or a multi-layered structure including, e.g., the above materials.

The interlayer insulating layer 117 may cover the upper electrode CE2. The interlayer insulating layer 117 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), zinc oxide (ZnO₂), or a combination thereof. The interlayer insulating layer 117 may include a single-layered structure or a multi-layered structure including, e.g., the inorganic insulating material.

A drain electrode SD1 and a source electrode SD2 may each be disposed on the interlayer insulating layer 117. The drain electrode SD1 and the source electrode SD2 may each be electrically connected to the semiconductor layer Act through contact holes formed in the first gate insulating layer 113, the second gate insulating layer 115, and the interlayer insulating layer 117. The drain electrode SD1 and the source electrode SD2 may each include a material having high conductivity. The drain electrode SD1 and the source electrode SD2 may each include a conductive material such as molybdenum (Mo), aluminum (Al), copper (Cu), titanium (Ti), or a combination thereof, and include a single-layered structure or a multi-layered structure including, e.g., the above materials. In an embodiment, the drain electrode SD1 and the source electrode SD2 may each have a multi-layered structure of Ti/Al/Ti. In an embodiment, one of the drain electrode SD1 and the source electrode SD2 may be omitted, and a portion of the semiconductor layer Act may be made conductive to replace this.

The planarization layer 119 may cover the first transistor TR1 and include a contact hole exposing a portion of the first transistor TR1. The planarization layer 119 may include an organic insulating layer. The planarization layer 119 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

A hydrogen supply layer 130 may be disposed on the planarization layer 119. The hydrogen supply layer 130 may include a first hydrogen supply layer 131 corresponding to the first pixel PX1 and a second hydrogen supply layer 132 corresponding to the second pixel PX2. The hydrogen supply layer 130 may be arranged to be adjacent to the first light-emitting diode LED1 and the second light-emitting diode LED2 to supply hydrogen to the emission layer. The hydrogen supply layer 130 may be described below in detail.

The display element layer DEL may be disposed on the pixel circuit layer PCL and the hydrogen supply layer 130. The display element layer DEL may include first to third light-emitting diodes LED1, LED2, and LED3 and the bank layer 120 under or/and on elements of the light-emitting diode. In an embodiment, the first and second light-emitting diodes LED1 and LED2 may be quantum-dot light-emitting elements, and the third light-emitting diode LED3 may be an organic light-emitting element. As an example, the first light-emitting diode LED1 configured to emit red light and the second light-emitting diode LED2 configured to emit green light may include an emission layer including quantum dots, and the third light-emitting diode LED3 configured to emit blue light may include an emission layer not including quantum dots and including only an organic material.

Each of the first to third light-emitting diodes LED1, LED2, and LED3 may include a portion of a pixel electrode arrangement 210. The pixel electrode arrangement 210 may include a first pixel electrode 211 forming the first light-emitting diode LED1, a second pixel electrode 212 forming the second light-emitting diode LED2, and a third pixel electrode 213 forming the third light-emitting diode LED3. The first to third pixel electrodes 211, 212, and 213 may be disposed on the pixel circuit layer PCL. The first pixel electrode 211 may be electrically connected to the drain electrode SD1 or the source electrode SD2 of the first transistor TR1 through a contact hole passing through the planarization layer 119. As shown in FIG. 5, the first pixel electrode 211, the second pixel electrode 212, and the third pixel electrode 213 may be apart from each other by a preset distance in a second direction (e.g., an x direction).

The pixel electrode arrangement 210 may be a reflective electrode, a semi-transmissive electrode, or a transmissive electrode. To form the pixel electrode which may be a transmissive electrode, indium tin oxide (ITO), indium zinc oxide (IZO), tin oxide (SnO₂), zinc oxide (ZnO), or any combination thereof can be used as a material for the pixel electrode. To form the pixel electrode arrangement 210 which may be a semi-transmissive electrode or a reflective electrode, magnesium (Mg), silver (Ag), aluminum (Al), aluminum-lithium (Al—Li), calcium (Ca), magnesium-indium (Mg—In), and magnesium-silver (Mg—Ag), or any combination thereof may be used as a material for the pixel electrode arrangement 210. The pixel electrode arrangement 210 may have a single-layered structure consisting of a single layer or a multi-layered structure including multiple layers. As an example, the pixel electrode arrangement 210 may have a three-layered structure of ITO/Ag/ITO.

The bank layer 120 may be disposed on the pixel circuit layer PCL. The bank layer 120 may cover the edges of the first to third pixel electrodes 211, 212, and 213. Specifically, the bank layer 120 may be in direct contact with the upper surface and the lateral surfaces of the end of the pixel electrodes of the pixel electrode arrangement 210. As shown in FIG. 5, in case that the hydrogen supply layer 130 is disposed under the pixel electrode arrangement 210, the bank layer 120 may also cover the edges of the hydrogen supply layer 130.

The bank layer 120 may include various materials. In an embodiment, the bank layer 120 may include an organic material such as acryl, BCB (benzocyclobutene), HMDSO (hexamethyldisiloxane), or a combination thereof. In an embodiment, the bank layer 120 may include a photoresist, that is, photosensitive resin. Specifically, the bank layer 120 may include a negative type photoresist that undergoes a reaction such as crosslinking upon light exposure.

The bank layer 120 may include a plurality of openings OP that may include the first opening 120OP1 exposing the central portion of the first pixel electrode 211, the second opening 120OP2 exposing the central portion of the second pixel electrode 212, and the third opening 120OP3 exposing the central portion of the third pixel electrode 213. As an example, the bank layer 120 may define the first emission area EA1 of the first light-emitting diode LED1, the second emission area EA2 of the second light-emitting diode LED2, and the third emission area EA3 of the third light-emitting diode LED3. The bank layer 120 may prevent arcs and the like from occurring at the edges of the pixel electrodes within the pixel electrode arrangement 210 by increasing a distance between the edges of the pixel electrodes within the pixel electrode arrangement 210 and an opposite electrode 230.

An emission layer 220 may be disposed in the opening of the bank layer 120. The emission layer 220 may include a first emission layer 221 forming the first light-emitting diode LED1, a second emission layer 222 forming the second light-emitting diode LED2, and a third emission layer 223 forming the third light-emitting diode LED3. As an example, the first emission layer 221 may be disposed on the first pixel electrode 211 and disposed in the first opening 120OP1. Likewise, the second emission layer 222 may be disposed on the second pixel electrode 212 and disposed in the second opening 120OP2. The third emission layer 223 may be disposed on the third pixel electrode 213 and disposed in the third opening 120OP3.

In an embodiment, the first emission layer 221 and the second emission layer 222 may include quantum dots. Specifically, the quantum dots included in the first emission layer 221 and the second emission layer 222 may serve as dopants, and the emission layer may further include a host and/or delayed fluorescent material. The quantum dots denote crystals of a semiconductor compound. The quantum dots may be configured to emit light in various emission wavelengths depending on the size of the crystal. The quantum dots may be configured to emit light in various emission wavelengths by adjusting the ratio of elements constituting the quantum dots. As an example, a diameter of the quantum dots may be in a range of about 1 nm to about 10 nm.

Quantum dots may be synthesized by a wet chemical process, a metal organic chemical vapor deposition process, a molecular beam epitaxy process, or a similar process. The wet chemical process may be a method of mixing an organic solvent with a precursor material and growing quantum dot crystals. In case that the crystals are grown, the organic solvent naturally acts as a dispersant coordinated on the surface of the quantum dot crystal and controls the growth of the crystal. Accordingly, the wet chemical process may be easier than vapor deposition such as metal organic chemical vapor deposition (MOCVD) or molecular beam epitaxy (MBE), and may be configured to control the growth of quantum dot particles through a process at low costs.

The quantum dot may include one of a Group II-VI semiconductor compound, a Group III-V semiconductor compound, a Group 1-III-VI semiconductor compound, a Group IV-VI semiconductor compound, a Group IV element or compound, and an arbitrary combination thereof.

Examples of a Group II-VI semiconductor compound may include one of a two-element compound including CdS, CdSe, CdTe, ZnS, ZnSe, ZnTe, ZnO, HgS, HgSe, HgTe, MgSe or MgS, but CdSeS, CdSeTe, CdSTe, ZnSeS, ZnSeTe, ZnSTe, ZnSTe, a three-element compound including HgSeS, HgSeTe, HgSTe, CdZnS, CdZnSe, CdZnTe, CdHgS, CdHgSe, CdHgTe, HgZnS, HgZnSe, HgZnTe, MgZnSe or MgZnS, CdZnSeS, CdZnSe, CdZnSeS, Cd CSeTSe, a four-element compound including HgZnSTe and the like, and an arbitrary combination thereof.

Examples of a Group III-V semiconductor compound may include one of a two-element compound including GaN, GaP, GaAs, GaSb, AlN, AlP, AlAs, AlSb, InN, InP, InAs, and InSb, a three-element compound including GaNP, GaNAs, GaNSb, GaPAs, GaPSb, AlNP, AlNAs, AlNSb, AlPAs, AlPSb, InGaP, InNP, InAIP, InNAs, InNSb, InPAs, and InPSb, and a four-element compound including GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and InAlPSb, and an arbitrary combination thereof. A Group III-V semiconductor compound may further include a Group II element. Examples of a Group III-V semiconductor compound further including a Group II element may include InZnP, InGaZnP, or InAlZnP.

Examples of a Group III-VI semiconductor compound may include one of a two-element compound including GaS, Ga₂S₃, GaSe, Ga₂Se₃, GaTe, InS, InSe, In₂S₃, In₂Se₃, and InTe, a three-element compound including InGaS₃ and InGaSe₃, and an arbitrary combination thereof.

Examples of a Group 1-III-VI semiconductor compound may include one of a three-element compound including AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and AgAlO₂, a four-element compound including AgInGaS₂, AgInGaSe₂, and CuInGaS, and an arbitrary combination thereof.

Examples of a Group IV-VI semiconductor compound may include one of a two-element compound including SnS, SnSe, SnTe, PbS, PbSe, and PbTe, a three-element compound including SnSeS, SnSeTe, SnSTe, PbSeS, PbSeTe, PbSTe, SnPbS, and SnPbSe, and SnPbTe, a four-element compound including SnPbSSe, SnPbSeTe, and SnPbSTe, and an arbitrary combination thereof.

Examples of a Group IV element or compound may include one of a single element including Si and Ge, a two-element compound including SiC and SiGe, and an arbitrary combination thereof.

Each element included in a multi-element compound such as a two-element compound, a three-element compound, and a four-element compound may be present in a particle in a uniform concentration or a non-uniform concentration. The chemical formula refers to the type of elements included in the compound, and the element ratio within the compound may be different. For example, AgInGaS₂ may mean AgInₓGa₁₋ₓS₂ (x may be a real number between 0 and 1).

A quantum dot may have a single structure in which the concentration of each element included in the relevant quantum dot may be uniform, or a double structure of a core-shell. As an example, a material of the core may be different from a material of the shell. The shell may cover at least a portion of the core.

The core may include, e.g., Cd, Zn, Hg, Mg, Ga, Al, In, Sn, Pb, Se, Te, P, or Sb.

The shell of a quantum dot may serve as a protective layer that prevents a chemical change of the core to maintain a semiconductor characteristic and/or serve as a charging layer for giving an electrophoretic characteristic to the quantum dot. The shell may include a single layer or a multi-layer. An interface between the core and the shell may have a concentration gradient in which the concentration of an element existing in the shell reduces toward the center.

Examples of the shell of the quantum dot include oxide of metal or non-metal, a semiconductor compound, or a combination thereof. Examples of oxides of metals or non-metals may include one of a two-element compound including SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and a three-element compound including MgAl₂O₄, CoFe₂O₄, NiFe₂O₄, CoMn₂O₄, and an arbitrary combination thereof.

Examples of the semiconductor compound may include one of a Group III-VI semiconductor compound, a Group II-VI semiconductor compound, a Group III-V semiconductor compound, a Group III-VI semiconductor compound, a Group 1-III-VI semiconductor compound, a Group IV-VI semiconductor compound, and an arbitrary combination thereof as described in the present specification. As an example, the semiconductor compound may include one of CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, and an arbitrary combination thereof.

Each element included in a multi-element compound such as a two-element compound, and a three-element compound may be present in a particle in a uniform concentration or a non-uniform concentration. The chemical formula refers to the type of elements included in the compound, and the element ratio within the compound may be different.

A quantum dot may have a full width of half maximum (FWHM) of a light emission wavelength spectrum of about 45 nm or less, specifically about 40 nm or less, and more specifically about 30 nm or less. Within this range, color purity or color reproduction may be improved. Because light emitted from the quantum dot may be emitted in all directions, a viewing angle of light may be improved.

The shape of the quantum dot may be a spherical shape, a pyramid shape, a multi-arm shape, a cubic shape, a nanoparticle, a nanotube, a nanowire, a nanofiber, a nano plate particle, or the like.

Because an energy band gap may be adjusted by adjusting the size of the quantum dot or the element ratio in the quantum dot compound, light in various wavelengths may be obtained from the quantum dot emission layer. Accordingly, the light-emitting element configured to emit light having various wavelengths may be implemented by using the quantum dots (using quantum dots of different sizes or using different element ratios in the quantum dot compound). Specifically, the size of the quantum dot or the element ratio in the quantum dot compound may be adjusted such that red, green, and/or blue light may be emitted. The quantum dots may be configured such that light in various colors may be combined to emit white light.

The third emission layer 223 may be an emission layer not including quantum dots and including only an organic material. Specifically, the third emission layer 223 may include an organic material including a fluorescent or phosphorous material emitting red, green, blue, or white light. The third emission layer 223 may be an organic emission layer including a low-molecular weight organic material or a polymer organic material. As an example, the third emission layer 223 may be an organic emission layer and may include copper phthalocyanine, tris-8-hydroxyquinoline aluminum, poly-phenylenevinylene-based material, polyfluorene-based material, or a combination thereof.

Although not shown in FIG. 5, the intermediate layer may further include a common layer disposed between the pixel electrode arrangement 210 and the emission layer 220 and/or between the emission layer 220 and the opposite electrode 230. Hereinafter, a common layer disposed between the pixel electrode arrangement 210 and the emission layer 220 may be referred to as a first common layer, and a common layer the emission layer 220 and the opposite electrode 230 may be referred to as a second common layer. The first common layer and the second common layer may each include an organic material.

The first common layer may be a hole transport region and may include a hole injection layer, a hole transport layer, an emission auxiliary layer, an electron blocking layer, or an arbitrary combination thereof. As an example, the first common layer may have a multi-layered structure of a hole injection layer/hole transport layer, a hole injection layer/hole transport layer/emission auxiliary layer, a hole injection layer/emission auxiliary layer, a hole transport layer/emission auxiliary layer, or a hole injection layer, which may be sequentially stacked on each other from the pixel electrode arrangement 210.

The second common layer may be an electron transport region and may include a buffer layer, a hole blocking layer, an electron control layer, an electron transport layer, an electron injection layer, or an arbitrary combination thereof. As an example, the electron transport region may have a structure of an electron transport layer/electron injection layer, a hole blocking layer/electron transport layer/electron injection layer, an electron control layer/electron transport layer/electron injection layer, or a buffer layer/electron transport layer/electron injection layer, which may be sequentially stacked on each other from the emission layer 220.

The opposite electrode 230 may cover the emission layer 220 and the bank layer 120. As an example, the opposite electrode 230 may be integrally provided to cover the entire surface of the substrate 100 to cover the first emission layer 221, the second emission layer 222, and the third emission layer 223. A metal, alloy, electrically conductive compound, or an arbitrary combination thereof having a low work function may be used as a material for the opposite electrode 230. The opposite electrode 230 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The opposite electrode 230 may be a transmissive electrode, a semi-transmissive electrode, or a reflective electrode. The opposite electrode 230 may have a single-layered structure, which may be a single layer, or a multi-layered structure having multiple layers.

The display apparatus 1 may have a structure including both a quantum-dot light-emitting element and an organic light-emitting element. The quantum-dot light-emitting element has an advantage of low manufacturing costs and excellent color coordinates. However, in the case of the light-emitting element configured to emit blue light, the organic light-emitting element may have an advantage of a longer lifespan than the quantum-dot light-emitting element. In the display apparatus according to an embodiment, because the first light-emitting diode LED1 and the second light-emitting diode LED2 employ the quantum-dot light-emitting elements, and the third light-emitting diode LED3 may employ the organic light-emitting element, color purity and color reproduction may be improved, and thus, the display apparatus may not only have excellent emission characteristics but also implement a long life effect, simultaneously. However, the embodiment may not be limited to the structure in which the first light-emitting diode LED1 and the second light-emitting diode LED2 employ the quantum-dot light-emitting elements, and the third light-emitting diode LED3 employs the organic light-emitting element. The first light-emitting diode LED1 or the second light-emitting diode LED2 may employ the organic light-emitting element, and the third light-emitting diode LED3 may employ the quantum-dot light-emitting element.

In an embodiment, the first emission layer 221 and the second emission layer 222, which may be emission layers including quantum dots, may include metal oxide containing Zn. As an example, the first emission layer 221 and the second emission layer 222 may further include ZnMgO. ZnMgO may be a material required to increase an emission efficiency and a lifespan efficiency of the first light-emitting diode LED1 and the second light-emitting diode LED2, which may be quantum-dot light-emitting elements. However, ZnMgO or ZnO may generate defects during a process of synthesizing a material for forming an emission layer, and the defects may deteriorate the emission efficiency and the lifespan of the light-emitting diode LED.

In contrast, in the display apparatus 1 according to an embodiment, because the hydrogen supply layer 130 may be arranged to overlap the first light-emitting diode LED1 and the second light-emitting diode LED2, defects due to ZnMgO may be reduced. The hydrogen supply layer 130 may be arranged to be adjacent to the quantum-dot light-emitting elements. Specifically, the hydrogen supply layer 130 may be disposed under the pixel electrode arrangement 210 of each of the first light-emitting diode LED1 and the second light-emitting diode LED2. In other words, the hydrogen supply layer 130 may be arranged not to overlap the third light-emitting diode LED3, which may be an organic light-emitting element, and not to be adjacent to the third light-emitting diode LED3.

In the embodiment of FIG. 5, the hydrogen supply layer 130 may include a first hydrogen supply layer 131 disposed under the first pixel electrode 211, and a second hydrogen supply layer 132 disposed under the second pixel electrode 212. The first hydrogen supply layer 131 may be contact with the bottom surface of the first pixel electrode 211, and the second hydrogen supply layer 132 may be contact with the bottom surface of the second pixel electrode 212. The first hydrogen supply layer 131 may have the same area as the first pixel electrode 211 in a plan view, and the second hydrogen supply layer 132 may have the same area as the second pixel electrode 212 in a plan view. Accordingly, the bank layer 120 may cover the ends of the first pixel electrode 211 and the first hydrogen supply layer 131 and the ends of the second pixel electrode 212 and the second hydrogen supply layer 132. However, the area of the hydrogen supply layer 130 does not necessarily have to be the same as the area of the corresponding pixel electrodes of the pixel electrode arrangement 210, and may be greater or less than the area of the corresponding pixel electrodes of the pixel electrode arrangement 210.

The hydrogen supply layer 130 may include an Si-based inorganic layer containing hydrogen. In an embodiment, the hydrogen supply layer 130 may contain hydrogen and may include at least one of silicon nitride (SiNₓ), silicon oxide (SiOₓ), and silicon oxynitride (SiON). As an example, the hydrogen supply layer 130 may include hydrogenated amorphous silicon nitride (a-SiN:H). Because the hydrogen supply layer 130 including hydrogenated amorphous silicon nitride (a-SiN:H) may be disposed to be in contact with the lower surface of the pixel electrode arrangement 210, hydrogen may be supplied to the emission layer 220 disposed on the pixel electrode arrangement 210. The first hydrogen supply layer 131 may be configured to supply hydrogen to the first emission layer 221 through the first pixel electrode 211, and the second hydrogen supply layer 132 may be configured to supply hydrogen to the second emission layer 222 through the second pixel electrode 212. The hydrogen supply layer 130 may contain a high hydrogen concentration to supply hydrogen to the first emission layer 221 and the second emission layer 222. As an example, the amount of hydrogen released from the hydrogen supply layer 130 may be 1.0E⁺²⁰ molecules/cm³ or more based on thermal desorption spectroscopy (TDS) analysis. The hydrogen supply layer 130 may contain more than 1.0E⁺²⁰ hydrogen molecules per cubic centimeter.

The thickness of the hydrogen supply layer 130 may be in a range of about 1000 Å to about 5000 Å. Specifically, the hydrogen supply layer 130 must have a thickness of at least about 1000 Å to smoothly supply hydrogen to the emission layer 220. However, in case that the thickness of the hydrogen supply layer 130 becomes excessively thick, the thickness of the display apparatus 1 also becomes thick, and therefore the thickness of the hydrogen supply layer 130 may be less than about 5000 Å. The thicknesses of the first pixel electrode 211 and the second pixel electrode 212 disposed on the hydrogen supply layer 130 may be in a range of about 500 Å to about 1500 Å. This is because, in case that the thicknesses of the first pixel electrode 211 and the second pixel electrode 212 are about 500 Å or less, it may be disadvantageous for current injection into the emission layer 220, and in case that the thicknesses of the first pixel electrode 211 and the second pixel electrode 212 are about 1500 Å or more, it may be difficult to supply hydrogen to the emission layer 220.

In case that the first emission layer 221 and the second emission layer 222 may be supplied with hydrogen by the hydrogen supply layer 130, ZnMgO contained in the first emission layer 221 and the second emission layer 222 reacts with hydrogen and defects may be reduced. Accordingly, the display apparatus 1 of FIG. 5 according to an embodiment may improve an emission efficiency and increase a lifespan by reducing defects in the first light-emitting diode LED1 and the second light-emitting diode LED2 that may include quantum dots.

To resolve defects due to ZnMgO in the quantum-dot emission layer, a process of coating a poly acrylate acid (PAA) solution to the encapsulation substrate 400 (see FIG. 3B) may be used. In case that the hydrogen supply layer 130 that uses hydrogenated silicon oxynitride (SiNₓ) is disposed under the pixel electrode arrangement 210 as in FIG. 5, mass productivity may be secured compared to the process using a PAA solution. Specifically, the method of applying the PAA solution to the sealing substrate 400 (FIG. 3b) and bonding it may cause defects such as fumes, but the hydrogen supply layer 130 shown in FIG. 5 may be deposited (e.g., directly deposited) on the substrate 100, and thus, defects such as fumes may be prevented. The PAA solution may be difficult to form uniformly because it must go through a process such as inkjet printing, slit coating, or spin coating on the encapsulation substrate 400 (FIG. 3), whereas the hydrogen supply layer 130 shown in FIG. 5 may be formed using a deposition method, and accordingly, the effect of uniform patterning may also be implemented. As a result, in the display apparatus according to an embodiment, not only defects may be reduced but also mass production may be also secured.

Although not shown in FIG. 5, to protect the light-emitting diode LED, an encapsulation member may be additionally disposed on the structure of FIG. 5. In an embodiment, the thin-film encapsulation layer TFE (see FIG. 3A) covering the first to third light-emitting diodes LED1, LED2, and LED3 may be disposed. The thin-film encapsulation layer TFE (see FIG. 3A) may include at least one inorganic encapsulation layer and at least one organic encapsulation layer, each covering the light-emitting diode LED. In an embodiment, the thin-film encapsulation substrate 400 (see FIG. 3B) covering the first to third light-emitting diodes LED1, LED2, and LED3 may be disposed. The encapsulation substrate 400 (see FIG. 3B) may extend to the substrate 100 through the sealing member 300 (see FIG. 3B) to encapsulate the light-emitting diode LED.

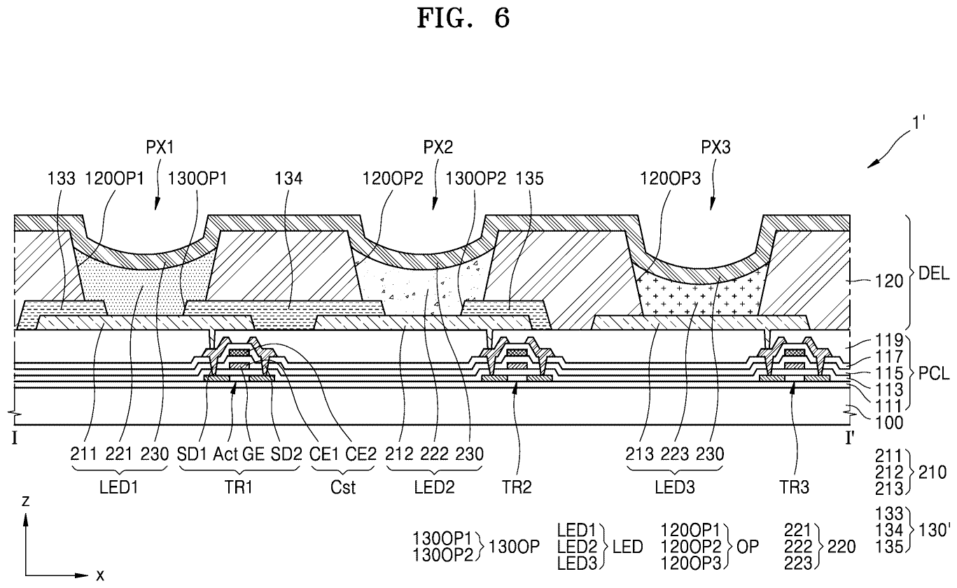

FIG. 6 is a schematic cross-sectional view of the display apparatus 1′ according to an embodiment. Referring to FIG. 6, the other characteristics except for the characteristic of the hydrogen supply layer 130 may be the same as those described with reference to FIGS. 4 and 5. Same reference numerals among elements of FIG. 6 are replaced with those previously described with reference to FIGS. 4 and 5, and differences may be described below.

Referring to FIG. 6, the first and second light-emitting diodes LED1 and LED2 may be quantum-dot light-emitting elements, and the third light-emitting diode LED3 may be an organic light-emitting element. The first and second emission layers 221 and 222 may include the emission material including quantum dots, and the third emission layer 223 may include the emission material including only the organic material. Accordingly, the display apparatus 1′ of FIG. 6 may have not only excellent emission characteristics by improving color purity and color reproduction, but also implement a long lifespan effect, simultaneously.

However, as described above, because the first emission layer 221 and the second emission layer 222 of the quantum-dot light-emitting elements include ZnMgO, defects may occur. In case that the hydrogen supply layer 130′ may be arranged to be adjacent to the quantum-dot light-emitting elements, for example, the first and second light-emitting diodes LED1 and LED2, hydrogen may be supplied to the first emission layer 221 and the second emission layer 222, and the ZnMgO in the first emission layer 221 and the second emission layer 222 may react with hydrogen and defects may be reduced.

In the display apparatus of FIG. 6, the hydrogen supply layer 130′ may be disposed on the pixel electrode arrangement 210. The hydrogen supply layer 130′ may cover the end of each of the first pixel electrode 211 and the second pixel electrode 212 and include a hydrogen supply layer opening 130OP exposing the central portion of each pixel electrode in pixel electrode arrangement 210. As an example, the hydrogen supply layer 130′ may include a first hydrogen supply layer opening 130OP1 exposing the central portion of the first pixel electrode 211 and a second hydrogen supply layer opening 130OP2 exposing the central portion of the second pixel electrode 212. The first hydrogen supply layer opening 130OP1 may overlap the first opening 120OP1 of the bank layer 120, and the second hydrogen supply layer opening 130OP2 may overlap the second opening 120OP2 of the bank layer 120. Accordingly, in a schematic cross-sectional view of FIG. 6 in a direction perpendicular to the substrate 100, the hydrogen supply layer 130′ may include a first portion 133 of the hydrogen supply layer, a second portion 134 of the hydrogen supply layer, and a third portion 135 of the hydrogen supply layer. However, the first portion 133 of the hydrogen supply layer, the second portion 134 of the hydrogen supply layer, and the third portion 135 of the hydrogen supply layer may be integral with each other.

The first portion 133 of the hydrogen supply layer 130′ may be arranged between the third pixel PX3 and the first pixel PX1 and be arranged to be adjacent to the first light-emitting diode LED1. The first portion 133 of the hydrogen supply layer 130′ may be arranged not to be adjacent to the third light-emitting diode LED3. Accordingly, the lateral surface of the first portion 133 of the hydrogen supply layer 130′ facing the first light-emitting diode LED1 may be in direct contact with the first emission layer 221, and the end of the first portion 133 facing an opposite side may be covered by the bank layer 120. In other words, the first portion 133 of the hydrogen supply layer 130′ may be arranged between the first pixel electrode 211 and the bank layer 120, and be in contact with only a portion of the bottom surface of the bank layer 120. As an example, a portion of the bottom surface of the bank layer 120 arranged between the first light-emitting diode LED1 and the third light-emitting diode LED3 may be in contact with the upper surface of the first portion 133 of the hydrogen supply layer 130′, and the remaining portion of the bottom surface of the bank layer 120 may be in contact with the upper surface of the planarization layer 119. The first portion 133 of the hydrogen supply layer 130′ may overlap a region corresponding to about half of the horizontal width of the bank layer 120 arranged between the first light-emitting diode LED1 and the third light-emitting diode LED3.

Likewise, the third portion 135 of the hydrogen supply layer may be arranged between the second pixel PX2 and the third pixel PX3 and be arranged to be adjacent to the second light-emitting diode LED2. The third portion 135 of the hydrogen supply layer 130′ may be arranged not to be adjacent to the third light-emitting diode LED3. Accordingly, the lateral surface of the third portion 135 of the hydrogen supply layer 130′ facing the second light-emitting diode LED2 may be in direct contact with the second emission layer 222, and the end of the third portion 135 facing an opposite side may be covered by the bank layer 120. In other words, the third portion 135 of the hydrogen supply layer 130′ may be arranged between the second pixel electrode 212 and the bank layer 120, and be in contact with only a portion of the bottom surface of the bank layer 120. As an example, a portion of the bottom surface of the bank layer 120 arranged between the second light-emitting diode LED2 and the third light-emitting diode LED3 may be in contact with the upper surface of the third portion 135 of the hydrogen supply layer 130′, and the remaining portion of the bottom surface of the bank layer 120 may be in contact with the upper surface of the planarization layer 119. The third portion 135 of the hydrogen supply layer 130′ may overlap a region corresponding to about half of the horizontal width of the bank layer 120 arranged between the second light-emitting diode LED2 and the third light-emitting diode LED3.

Because the second portion 134 of the hydrogen supply layer 130′ may be arranged between the first light-emitting diode LED1 and the second light-emitting diode LED2, which may be quantum-dot light-emitting elements, the second portion 134 of the hydrogen supply layer 130′ may be arranged to be adjacent to the first light-emitting diode LED1, and thus, may extend to be adjacent to the second light-emitting diode LED2. The second portion 134 of the hydrogen supply layer 130′ may be continuously disposed on the first pixel electrode 211 and the second pixel electrode 212 to cover the ends of the first pixel electrode 211 and the second pixel electrode 212. Accordingly, the lateral surface of the second portion 134 of the hydrogen supply layer 130′ facing the first light-emitting diode LED1 may be in contact (e.g., direct contact) with the first emission layer 221, and the lateral surface of the second portion 134 of the hydrogen supply layer 130′ facing the second light-emitting diode LED2 may be in contact (e.g., direct contact) with the second emission layer 222. The bank layer 120 arranged between the first light-emitting diode LED1 and the second light-emitting diode LED2 may be disposed on the second portion 134 of the hydrogen supply layer 130′. The entire bottom surface of the bank layer 120 arranged between the first light-emitting diode LED1 and the second light-emitting diode LED2 may be in contact with the upper surface of the second portion 134 of the hydrogen supply layer 130′.

As in FIG. 5, the hydrogen supply layer 130′ of FIG. 6 may contain high a hydrogen concentration and may include at least one of silicon nitride (SiNₓ), silicon oxide (SiOₓ), and silicon oxynitride (SiON). Because the lateral surface of the hydrogen supply layer 130′ facing the first hydrogen supply layer opening 130OP1 may be in contact with the first emission layer 221, and the lateral surface of the hydrogen supply layer 130′ facing the second hydrogen supply layer opening 130OP2 may be in contact with the second emission layer 222, the hydrogen supply layer 130′ of FIG. 6 may be configured to supply hydrogen to the first emission layer 221 and the second emission layer 222. Because ZnMgO included in the first emission layer 221 and the second emission layer 222 reacts with hydrogen and defects may be reduced, an emission efficiency of the quantum-dot light-emitting element may be improved and a lifespan may be increased even in the display apparatus 1′ according to an embodiment as in FIG. 6. Because the hydrogen supply layer 130′ may be deposited (e.g., directly deposited) on the substrate 100 even in the display apparatus 1′ shown in FIG. 6, mass production may be also secured even in the display apparatus 1′ according to an embodiment.

The thickness of the hydrogen supply layer 130′ may be in a range of about 1000 Å to about 5000 Å. Specifically, the hydrogen supply layer 130′ must have a thickness of at least about 1000 Å to swiftly supply hydrogen to the emission layer 220. However in case that the thickness of the hydrogen supply layer 130′ becomes excessively thick, the thickness of the display apparatus 1′ also becomes thick, and therefore the thickness of the hydrogen supply layer 130′ may be less than about 5000 Å.

Although not shown in FIG. 6, to protect the light-emitting diode LED, a sealing member may be additionally disposed on the structure of FIG. 6. In an embodiment, the thin-film encapsulation layer TFE (see FIG. 3A) covering the first to third light-emitting diodes LED1, LED2, and LED3 may be disposed. The thin-film encapsulation layer TFE (see FIG. 3A) may include at least one inorganic encapsulation layer and at least one organic encapsulation layer, each covering the light-emitting diode LED. In an embodiment, the thin-film encapsulation substrate 400 (see FIG. 3B) covering the first to third light-emitting diodes LED1, LED2, and LED3 may be disposed. The encapsulation substrate 400 (see FIG. 3B) may extend to the substrate 100 through the sealing member 300 (see FIG. 3B) to encapsulate the light-emitting diode LED.

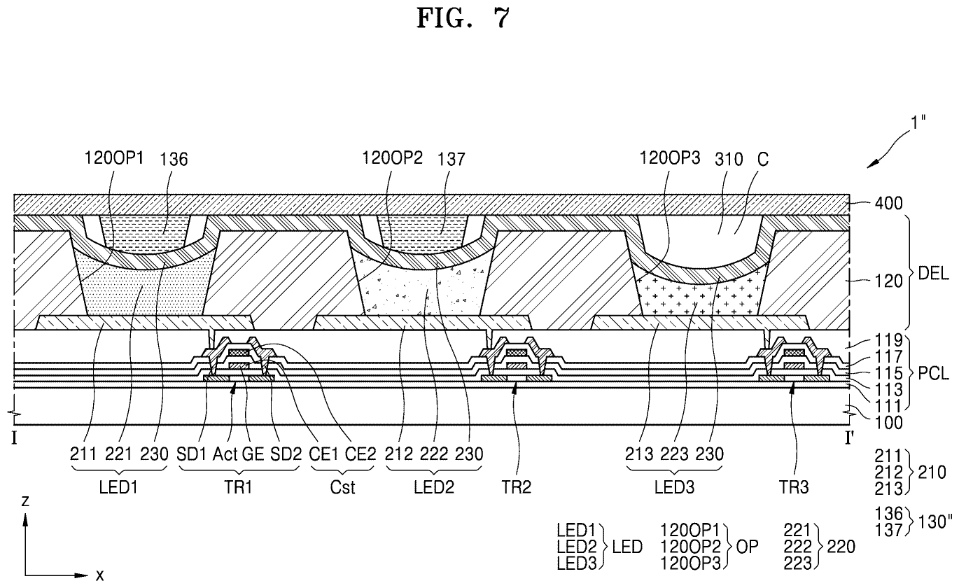

FIG. 7 is a schematic cross-sectional view of the display apparatus 1″ according to an embodiment. Referring to FIG. 7, other characteristics except for those of the encapsulation substrate 400 and the hydrogen supply layer 130 may be the same as those described with reference to FIGS. 4 and 5. Same reference numerals among elements of FIG. 7 may be replaced with those previously described with reference to FIGS. 4 and 5, and differences may be described below.

Referring to FIG. 7, the first and second light-emitting diodes LED1 and LED2 may be quantum-dot light-emitting elements, and the third light-emitting diode LED3 may be an organic light-emitting element. The first and second emission layers 221 and 222 may include the emission material including quantum dots, and the third emission layer 223 may include the emission material including only the organic material. Accordingly, the display apparatus 1 of FIG. 7 may have not only excellent emission characteristics by improving color purity and color reproduction, but also implement a long lifespan effect, simultaneously.

However, as described above, because the first emission layer 221 and the second emission layer 222 of the quantum-dot light-emitting elements include ZnMgO, defects may occur. In case, that the hydrogen supply layer 130 may be arranged to be adjacent to the quantum-dot light-emitting elements, s hydrogen may be supplied to the first emission layer 221 and the second emission layer 222, and ZnMgO may react with hydrogen and defects may be reduced.

In the display apparatus 1″ of FIG. 7, the hydrogen supply layer 130″ may be disposed on the encapsulation substrate 400. Here, the phrase ‘disposed on the encapsulation substrate 400’ may mean that the hydrogen supply layer 130 may be formed (e.g., directly formed) on the layers disposed on the encapsulation substrate 400 to implement the encapsulation substrate 400. In other words, hydrogen supply layer 130″ may be defined on the surface (the bottom surface) of the encapsulation layer 400 in a direction facing the substrate 100. The encapsulation substrate 400 may include glass or a light-transmissive organic material. As an example, the encapsulation substrate 400 may include a light-transmissive organic material such as an acryl-based resin.

Accordingly, the first hydrogen supply layer 136 may be disposed on the bottom surface of the encapsulation substrate 400 and may overlap the first light-emitting diode LED1, and the second hydrogen supply layer 137 may be disposed on the bottom surface of the encapsulation substrate 400 and may overlap the second light-emitting diode LED2. Accordingly, the first hydrogen supply layer 136 may be disposed on a portion of the opposite electrode 230 corresponding to the first light-emitting diode LED1, and the second hydrogen supply layer 137 may be disposed on a portion of the opposite electrode 230 corresponding to the second light-emitting diode LED2. In an embodiment, each of the first hydrogen supply layer 136 and the second hydrogen supply layer 137 may be in contact with the upper surface of the opposite electrode 230. However, the embodiment may not be limited thereto and the hydrogen supply layer 130″ may be arranged to be apart from the opposite electrode 230 by an interval.

Like FIG. 5, the hydrogen supply layer 130″ of FIG. 7 may contain a high hydrogen concentration and may further include at least one of silicon nitride (SiNₓ), silicon oxide (SiOₓ), and silicon oxynitride (SiON). Accordingly, the first hydrogen supply layer 136 may be configured to supply hydrogen to the first emission layer 221 through the opposite electrode 230 of the first light-emitting diode LED1, and the second hydrogen supply layer 137 may be configured to supply hydrogen to the second emission layer 222 through the opposite electrode 230 of the second light-emitting diode LED2. Because ZnMgO included in the first emission layer 221 and the second emission layer 222 reacts with the hydrogen and defects may be reduced, an emission efficiency of the quantum-dot light-emitting element may be improved and a lifespan may be increased even in the display apparatus 1″ according to an embodiment as in FIG. 7.

Because the hydrogen supply layer 130″ includes hydrogenated silicon nitride (SiNₓ), the hydrogen supply layer 130″ may be deposited on the encapsulation substrate 400 through chemical vapor deposition (CVD) instead of inkjet printing, spin coating, and slit coating. Accordingly, in the display apparatus 1″ shown in FIG. 7 that uses the hydrogen supply layer 130″, fume occurrence may be prevented compared to the case of using the above-described PAA solution, and the hydrogen supply layer 130″ may be uniformly patterned, and thus, mass productivity may be improved.

The thickness of the hydrogen supply layer 130″ may be in a range of about 1000 Å to about 5000 Å. Specifically, the hydrogen supply layer 130″ must have a thickness of at least about 1000 Å to swiftly supply hydrogen to the emission layer 220. However in case that the thickness of the hydrogen supply layer 130″ becomes excessively thick, the thickness of the display apparatus 1″ also becomes thick, and therefore the thickness of the hydrogen supply layer 130″ may be about 5000 Å or less.

The encapsulation substrate 400 may be bonded to the substrate 100 such that the first light-emitting diode LED1 and the second light-emitting diode LED2 respectively face the first hydrogen supply layer 136 and the second hydrogen supply layer 137. Accordingly, light emitted from the first light-emitting diode LED1 may be emitted through the first hydrogen supply layer 136, and light emitted from the second light-emitting diode LED2 may be emitted through the second hydrogen supply layer 137.

The substrate 100 may extend to the encapsulation substrate 400 through a sealing member (not shown). The sealing member may be arranged in the non-display area NDA (see FIG. 1) and may be arranged to surround the display area DA (see FIG. 1). As an example, in case that viewed in a direction (a z axis direction) perpendicular to the upper surface of the display apparatus 1″, the sealing member may have a closed-loop shape surrounding the display area DA. The sealing member may include sealant, frit, and the like. The sealing member may include a light-curable resin cured by an ultraviolet radiation and the like. The sealing member and the encapsulation substrate 400 may completely block the light-emitting diode LED of the display apparatus 1″ from the outside. A cavity C may be defined between the substrate 100 and the encapsulation substrate 400 by the sealing member. The cavity C may be an empty space in which a filler may not be disposed. In case that there is the cavity C between the hydrogen supply layer 130″ and the opposite electrode 230, the hydrogen supply layer 130″ may be configured to supply hydrogen to the first emission layer 221 and the second emission layer 222.

In the display apparatus according to an embodiment where the hydrogen supply layer may be included, an emission efficiency and a lifespan of the light-emitting element may be improved. However, this effect may be an example, and the scope of the disclosure may not be limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first light-emitting diode, a second light-emitting diode, and a third light-emitting diode disposed on the substrate and configured to emit light of different colors;
a bank layer disposed on the substrate; and
a hydrogen supply layer arranged to overlap or to be adjacent to each of the first light-emitting diode and the second light-emitting diode,
wherein the first, second and third light-emitting diodes each include:
a pixel electrode disposed on the substrate, the bank layer including an opening exposing a central portion of the pixel electrode;
an intermediate layer disposed on the pixel electrode and in the opening; and
an opposite electrode disposed on the intermediate layer and on the bank layer.

2. The display apparatus of claim 1, wherein
the hydrogen supply layer does not overlap the third light-emitting diode, and
the hydrogen supply layer is arranged not to be adjacent to the third light-emitting diode.

3. The display apparatus of claim 1, wherein the hydrogen supply layer comprises:
hydrogen; and
at least one of silicon nitride (SiNₓ), silicon oxide (SiOₓ), and silicon oxynitride (SiON).

4. The display apparatus of claim 1, wherein
the first light-emitting diode includes a first pixel electrode, the second light-emitting diode includes a second pixel electrode, and the third light-emitting diode includes a third pixel electrode,
the bank layer includes a first opening exposing a central portion of the first pixel electrode, a second opening exposing a central portion of the second pixel electrode, and a third opening exposing a central portion of the third pixel electrode, and
the first light-emitting diode further includes a first intermediate layer disposed in the first opening, the second light-emitting diode further includes a second intermediate layer disposed in the second opening, and the third light-emitting diode further includes a third intermediate layer disposed in the third opening.

5. The display apparatus of claim 4, wherein the hydrogen supply layer is disposed under and is overlapped by each of the first pixel electrode and the second pixel electrode.

6. The display apparatus of claim 5, wherein an upper surface of the hydrogen supply layer is in contact with a bottom surface of at least one of the first pixel electrode and the second pixel electrode.

7. The display apparatus of claim 5, wherein the bank layer covers ends of each of the first pixel electrode, the second pixel electrode, and the hydrogen supply layer.

8. The display apparatus of claim 5, wherein in a plan view, the hydrogen supply layer and at least one of the first pixel electrode and the second pixel electrode have a same area.

9. The display apparatus of claim 5, wherein a thickness of each of the first pixel electrode and the second pixel electrode is in a range of about 500 Å to about 1,500 Å.

10. The display apparatus of claim 4, wherein
the hydrogen supply layer is disposed on an upper portion of the first pixel electrode and an upper portion of the second pixel electrode, and
the hydrogen supply layer includes a first hydrogen supply layer opening exposing the central portion of the first pixel electrode and a second hydrogen supply layer opening exposing the central portion of the second pixel electrode.

11. The display apparatus of claim 10, wherein the hydrogen supply layer covers ends of the first pixel electrode and the second pixel electrode.

12. The display apparatus of claim 10, wherein
a lateral surface of the hydrogen supply layer facing the first light-emitting diode is in direct contact with the first intermediate layer, and
a lateral surface of the hydrogen supply layer facing the second light-emitting diode is in direct contact with the second intermediate layer.

13. The display apparatus of claim 10, wherein
the first hydrogen supply layer opening overlaps the first opening, and
the second hydrogen supply layer opening overlaps the second opening.

14. The display apparatus of claim 10, wherein the bank layer is disposed on the hydrogen supply layer.

15. The display apparatus of claim 14, wherein an entire lower surface of the bank layer arranged between the first light-emitting diode and the second light-emitting diode is in contact with an upper surface of the hydrogen supply layer.

16. The display apparatus of claim 14, further comprising:
a planarization layer disposed under each of the first pixel electrode, the second pixel electrode, and the third pixel electrode,
wherein a portion of a lower surface of the bank layer arranged between the first light-emitting diode and the third light-emitting diode is in contact with an upper surface of the hydrogen supply layer, and a remaining portion is in contact with an upper surface of the planarization layer.

17. The display apparatus of claim 16, wherein
a portion of the lower surface of the bank layer arranged between the second light-emitting diode and the third light-emitting diode is in contact with the upper surface of the hydrogen supply layer, and
a remaining portion is in contact with the upper surface of the planarization layer.

18. The display apparatus of claim 4, further comprising:
an encapsulation substrate disposed on each of the first light-emitting diode, the second light-emitting diode, and the third light-emitting diode; and
a sealing member coupling the substrate to the encapsulation substrate,
wherein the hydrogen supply layer is in contact with a surface of the encapsulation substrate facing the substrate.

19. The display apparatus of claim 18, wherein the hydrogen supply layer is arranged to overlap each of the first intermediate layer and the second intermediate layer.

20. The display apparatus of claim 18, wherein the hydrogen supply layer is in contact with an upper surface of the opposite electrode.

21. The display apparatus of claim 4, wherein
each of the first intermediate layer and the second intermediate layer includes an emission layer including a plurality of quantum dots, and
the third intermediate layer includes an emission layer composed of an organic material.

22. The display apparatus of claim 1, wherein a thickness of the hydrogen supply layer is in a range of about 1,000 Å to about 5,000 Å.

23. The display apparatus of claim 1, wherein
the first light-emitting diode is configured to emit light in a wavelength band of about 580 nm to about 780 nm,
the second light-emitting diode is configured to emit light in a wavelength band of about 495 nm to about 580 nm, and
the third light-emitting diode is configured to emit light in a wavelength band of about 380 nm to about 495 nm.

24. A display apparatus comprising:
a substrate;
a quantum-dot light-emitting element disposed on the substrate;
an organic light-emitting element are disposed on the substrate a bank layer disposed on the substrate; and
a hydrogen supply layer arranged to overlap or to be adjacent to the quantum-dot light-emitting element, wherein the quantum-dot light-emitting element and the organic light-emitting element each include:
a pixel electrode disposed on the substrate, the bank layer including an opening exposing a central portion of the pixel electrode;
an intermediate layer disposed on the pixel electrode and in the opening; and
an opposite electrode covering the intermediate layer and on the bank layer.

25. The display apparatus of claim 24, wherein
the intermediate layer of the quantum-dot light-emitting element includes an emission layer that includes a plurality of quantum dots, and
the intermediate layer of the organic light-emitting element includes an emission layer that is composed of an organic material.

26. The display apparatus of claim 24, wherein the hydrogen supply layer does not overlap the organic light-emitting element and is arranged not to be adjacent to the organic light-emitting element.

27. The display apparatus of claim 24, wherein the hydrogen supply layer overlaps the pixel electrode of the quantum-dot light-emitting element and is disposed under the pixel electrode of the quantum-dot light-emitting element.

28. The display apparatus of claim 24, wherein the hydrogen supply layer is disposed on the pixel electrode of the quantum-dot light-emitting element and includes a hydrogen supply layer opening exposing the central portion of the pixel electrode.

29. The display apparatus of claim 24, further comprising:
an encapsulation substrate disposed on each of the quantum-dot light-emitting element and the organic light-emitting element; and
a sealing member coupling the substrate to the encapsulation substrate,
wherein the hydrogen supply layer is in direct contact with a surface of the encapsulation substrate facing the substrate.

30. The display apparatus of claim 29, wherein the hydrogen supply layer is arranged to overlap the intermediate layer of the quantum-dot light-emitting element.
